(19) United States
(12) Patent Application Publication
(10) Pub. No.: US 2022/0396154 A1
(43) Pub. Date: Dec. 15, 2022

(54) VEHICLE MOUNTED ELECTRIC POWER CONVERTER

(71) Applicant: Panasonic Intellectual Property Management Co., Ltd., Osaka (JP)

(72) Inventor: Ryo ISHIKAWA, Kanagawa (JP)

(21) Appl. No.: 17/346,593

(22) Filed: Jun. 14, 2021

(51) Int. Cl. B60L 15/00; H05K 7/20; H02M 7/217

(52) U.S. Cl. CPC B60L 15/007; H05K 7/20918; H02M 7/217; H05K 7/1432

(57) ABSTRACT

A vehicle mounted electrical power converter includes: a heatsink; a circuit board placed on or above the heatsink; a power semiconductor device mounted on or above the circuit board; a control board support base that is placed on and/or above the circuit board and that supports a control board; and a heat transfer member being interposed between the power semiconductor device and the control board support base and thermally coupling between the power semiconductor device and the control board support base.

### TECHNICAL FIELD

The present disclosure relates to a vehicle mounted electric power converter.

### BACKGROUND ART

Electric power converters (e.g., DC/DC converters, inverters, and chargers) mounted on electric vehicles and/or hybrid vehicles have been known (e.g., see PTL 1).

In electric power converters of this type (typically, inverters), it is known that during acceleration traveling and/or slope-climbing traveling of vehicles, the output increases approximately twice the output during constant speed traveling about a few tens of seconds and power semiconductor devices forming the electric power converters rapidly generate heat. Such overheating of power semiconductor devices causes deterioration of device characteristics and/or damages on the devices, so that such overheated states of the power semiconductor devices need to be avoided.

In order to cope with such instantaneous heat generation of a power semiconductor device, improving the heat dissipation capability of a heatsink itself for absorbing the heat generated in the power semiconductor device has been discussed, heretofore. In order to improve the heat dissipation capability of the heatsink itself, however, an increase in size of the heatsink or use of a cooling medium having a high heat transport capability is required, and there arises a problem leading to an increase in cost or size of the electric power converters.

### CITATION LIST

### Patent Literature

### PTL 1

### Japanese Patent Application Laid-Open No. 2013-031250

### SUMMARY OF INVENTION

### Solution to Problem

The present disclosure has been made in view of the abovementioned problem and thus aims at providing a vehicle mounted electric power converter capable of coping with instantaneous heat generation of a power semiconductor device, with a simple configuration.

The present disclosure mainly solving the problem above is directed to a vehicle mounted electrical power converter including: a heatsink; a circuit board placed on or above the heatsink; a power semiconductor device mounted on or above the circuit board; a control board support base that is placed on and/or above the circuit board and that supports a control board; and a heat transfer member being interposed between the power semiconductor device and the control board support base and thermally coupling between the power semiconductor device and the control board support base.

### Advantageous Effects of Invention

A vehicle mounted electric power converter according to the present disclosure is capable of coping with instantaneous heat generation of a power semiconductor device, with a simple configuration.

### BRIEF DESCRIPTION OF DRAWINGS

FIG. 1 is a side view of a configuration of an electric power converter according to an embodiment;

FIG. 2 is an exploded perspective view of the configuration of the electric power converter according to the embodiment;

FIG. 3 is a circuit block diagram of the electric power converter according to the embodiment; and

FIG. 4 is a diagram provided for describing heat transmission paths in the electric power converter according to the embodiment.

### DESCRIPTION OF EMBODIMENTS

Hereinafter, a preferred embodiment of the present disclosure will be described in detail with reference to the accompanying drawings. Note that, in this specification and drawings, configuration elements having substantially the same functions are denoted by the same reference numerals and redundant descriptions thereof are omitted.

Note that, hereinafter, a description will be given while an upper direction of the drawings is referred to as “upward” and a lower direction of the drawings is referred to as “downward” in order to clarify a positional relationship of the configuration elements. These directions, however, are not intended to limit the postures of vehicle mounted electric power convers at the time of usage.

### Configuration of Vehicle Mounted Electric Power Converter

Hereinafter, an exemplary configuration of a vehicle mounted electric power converter (hereinafter, abbreviated to “power converter”) according to the present embodiment will be described. Power converter 1 according to the present embodiment is applied to, for example, a vehicle mounted inverter for outputting an AC power to a motor that drives the vehicle.

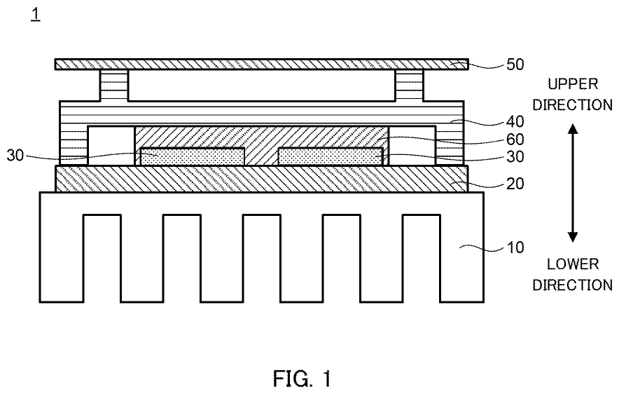

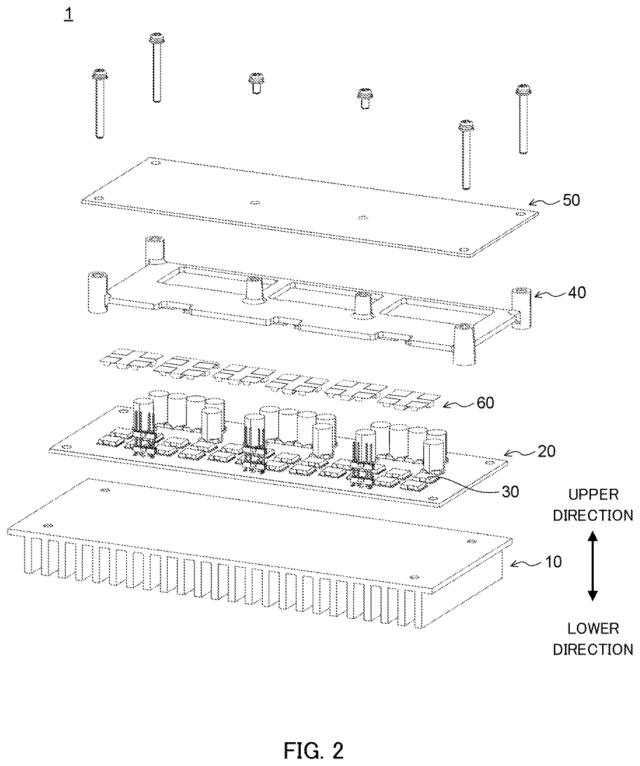

FIG. 1 is a side view of a configuration of power converter 1 according to the present embodiment. FIG. 2 is an exploded perspective view of the configuration of power converter 1 according to the present embodiment. Note that, in FIG. 1, for convenience of description, power converter 1 are drawn by schematically illustrating actual power converter 1 illustrated in FIG. 2.

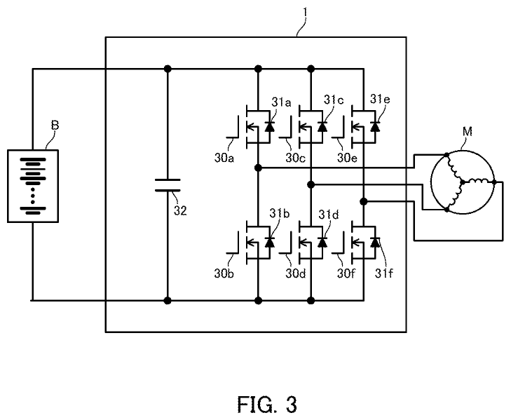

FIG. 3 is a circuit block diagram of power converter 1 according to the present embodiment.

Power converter 1 includes heatsink 10, circuit board 20, power semiconductor devices 30, control board support base 40, control board 50, and heat transfer members 60. Note that, circuit board 20, power semiconductor device 30, control board support base 40, control board 50, and heat transfer members 60 are housed in a housing (not illustrated) integrally formed with heatsink 10.

Heatsink 10 dissipates heat generated in circuit board 20 (i.e., heat generated by power semiconductor devices 30) to outside of power converter 1. Heatsink 10 includes, for example, a base plate for supporting circuit board 20 and heat dissipation fins extending downward from the base plate.

Note that, heatsink 10, for example, is integrally formed with a housing (not illustrated) of power converter 1, and the base plate serves as a wall surface of the housing. Power converter 1 is then installed at a position such that the heat dissipation fins of heatsink 10 are positioned within a passage of the cooling medium (e.g., air cooling medium).

Circuit board 20 is a board including a circuit (an inverter circuit, herein) for realizing the power conversion functions of power converter 1. Circuit board 20 is, for example, a metal board (e.g., aluminum board), and a board obtained by forming an insulating film (e.g., epoxy resin) on a metal board serving as a base and then forming a wiring pattern on the insulating film is used. Metal boards are useful in that they have favorable heat dissipation properties.

Power semiconductor devices 30 are each a semiconductor component for power conversion serving as a switching element in the circuit of power converter 1. As power semiconductor device 30, for example, a discrete device of Insulated Gate Bipolar Transistor (IGBT) or Metal-Oxide-Semiconductor Field-Effect Transistor (MOSFET) is used. Note that, although a discrete device is used as power semiconductor device 30, herein, a module component in which a plurality of IGBTs or MOSFETs is housed in a single package may be used as power semiconductor devices 30.

In the present embodiment, as the inverter circuit, a three-phase bridge inverter including the following components is used as illustrated in FIG. 3: smoothing capacitor 32; power semiconductor devices 30 (30a and 30b) forming a U-phase arm; power semiconductor devices 30 (30c and 30d) forming a V-phase arm; power semiconductor devices 30 (30e and 30f) forming a W-phase arm; and freewheeling diodes 31a to 31f (not illustrated in FIG. 1 or 2) provided in parallel with these power semiconductor devices 30 (30a to 30f), respectively. More specifically, six power semiconductor devices 30 (MOSFETs, herein) are mounted on circuit board 20 according to the present embodiment. Smoothing capacitor 32 and freewheeling diodes 31a to 31f are mounted on circuit board 20 together with power semiconductor devices 30.

Note that, battery B is connected to an input stage of the inverter circuit while motor M is connected to an output stage (U-phase arm, V-phase arm, and W-phase arm) of the inverter circuit.

Power semiconductor devices 30, for example, are installed in a lateral state (i.e., flat state) so as to be in contact with circuit board 20 at their heat dissipation surfaces (lower surfaces in FIG. 1). The heat generated in power semiconductor devices 30 is discharged to heatsink 10 via circuit board 20. Note that, the upper surfaces of power semiconductor devices 30 are in contact with heat transfer member 60, and the heat generated in power semiconductor devices 30 may be discharged as well to control board support base 40 via heat transfer member 60.

Control board support base 40 is placed on and above circuit board 20 and supports control board 50. Control board support base 40, for example, has a tower-shaped structure and is placed above power semiconductor devices 30 while being spaced apart from power semiconductor devices 30.

Control board support base 40 is formed typically of a metal material so as to be capable of absorbing the heat discharged from power semiconductor devices 30. Note that, control board support base 40 is interposed between circuit board 20 and control board 50 and thus serves as an electrical noise shield between circuit board 20 and control board 50 as well.

A microcomputer (equivalent to “control circuit” of the present invention) for generating a control signal (e.g., PWM signal) for controlling switching of power semiconductor devices 30 (e.g., PWM signal), for example, is mounted on or above control board 50. The microcomputer on control board 50 thus controls an on/off operation of power semiconductor devices 30 with a control signal and performs power conversion (DA conversion, herein) of the power input to power semiconductor devices 30. Note that, sensor signals from a current sensor for detecting a current value supplied to motor M and a sensor signal from a rotational speed sensor and/or the like for detecting a rotational position of a rotor of motor M are input to control board 50, for example.

Heat transfer member 60 is interposed between power semiconductor devices 30 and control board support base 40 and thermally couples between power semiconductor devices 30 and control board support base 40. When power semiconductor devices 30 generate heat rapidly (typically, during acceleration traveling and/or slope-climbing traveling of vehicle), heat transfer member 60 diffuses the heat of power semiconductor devices 30 to control board support base 40 (details will be given, hereinafter).

Note that, heat transfer member 60 is disposed so as to cover the upper surface of each of the plurality of power semiconductor devices 30 mounted on circuit board 20. Thus, each of the plurality of power semiconductor devices 30 is thermally coupled to control board support base 40 via heat transfer member 60.

Heat transfer member 60 is formed of, for example, a resin material having high thermal conductivity, typically, a gap filler, a potting material or a heat dissipation pad. Heat transfer member 60 is placed so as to fill a gap between power semiconductor devices 30 and control board support base 40 and to be in close contact with power semiconductor devices 30 and with control board support base 40. Note that, for the purpose of ensuring electrical insulation between power semiconductor devices 30 and control board support base 40, a material having an insulating property is favorably used for heat transfer member 60. The material forming heat transfer member 60 may be any material as long as the material is capable of thermally coupling between power semiconductor devices 30 and control board support base 40, however.

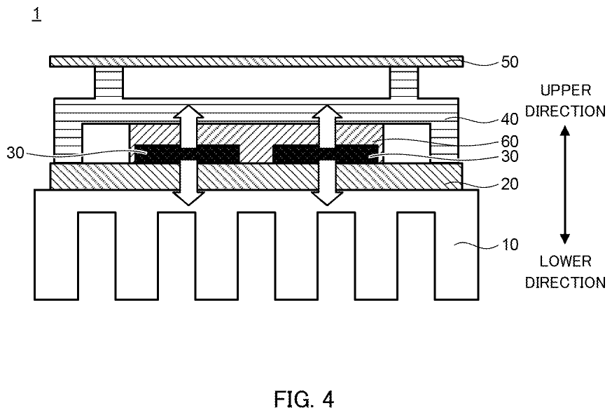

FIG. 4 is a diagram provided for describing heat transfer paths in power converter 1 according to the present embodiment. Arrows in FIG. 4 represent heat flows of heat generated from power semiconductor devices 30. The state is illustrated herein, where power semiconductor devices 30 generate heat rapidly along with an increase in output of the inverter during acceleration traveling or slope-climbing traveling of a vehicle.

The heat generated from power semiconductor devices 30 transfers to heat sink 10 via the lower surfaces (heat dissipation surfaces) of power semiconductor devices 30. The heat generated from power semiconductor devices 30 is mostly discharged outside via heatsink 10.

When the vehicle is accelerating or climbing a slope, the amount of heat generated by power semiconductor devices 30 temporarily increases compared with that in a normal running state, however. For this reason, suppose a case where heat dissipation of power semiconductor devices 30 is performed by heatsink 10 alone, power semiconductor devices 30 turn into an overheated state.

In this regard, power converter 1 according to the present embodiment is configured to be capable of diffusing the heat of power semiconductor devices 30 to control board support table 40 via heat transfer member 60. Since control board support base 40 itself has no heat dissipation function, the heat received by control board support base 40 from power semiconductor devices 30 is accumulated in control board support base 40. The heat of power semiconductor devices 30, however, is discharged temporarily to control board support base 40 in addition to heatsink 10. Thus, the heat dissipation capability of power semiconductor devices 30 practically increases. Accordingly, the overheated state of power semiconductor devices 30 can be avoided.

### Effects

As described above, power converter 1 according to the present embodiment is capable of diffusing the heat rapidly generated from power semiconductor devices 30 during acceleration or slop-climbing of a vehicle to control board support base 40 temporarily, and suppressing an overheated state of these power semiconductor devices 30. In particular, power converter 1 according to the present embodiment is useful in making it possible to suppress an overheated state of power semiconductor devices 30 without an increase in size of heatsink 10.

In addition, power converter 1 according to the present embodiment is capable of forming an electrical noise shield between circuit board 20 and control board 50 by control board support base (typically, formed of a metal material) 40.

Further, although various examples have been thus far, naturally, various changes may be made in forms and details without departure from the spirit and scope of the present invention and the invention in claims to be described, hereinafter.

The present application is entitled to and claims the benefit of Japanese Patent Application No. 2019-207073, filed on Nov. 15, 2019, and the disclosure of which including the specification, drawings, and abstract is incorporated herein by reference in its entirety.

### INDUSTRIAL APPLICABILITY

The power converter according to the present invention is capable of coping with instantaneous heat generation of a power semiconductor device, with a simple configuration.

1. A vehicle mounted electrical power converter, comprising:
a heatsink;
a circuit board placed on or above the heatsink;
a power semiconductor device mounted on or above the circuit board;
a control board support base that is placed on and/or above the circuit board and that supports a control board; and
a heat transfer member being interposed between the power semiconductor device and the control board support base and thermally coupling between the power semiconductor device and the control board support base.

2. The vehicle mounted electrical power converter according to claim 1, wherein the heat transfer member is a gap filler, a potting material or a heat dissipation pad.

3. The vehicle mounted electrical power converter according to claim 1, wherein the control board support base is formed of a metal material.

4. The vehicle mounted electrical power converter according to claim 1, wherein
a plurality of the power semiconductor devices are mounted on or above the circuit board, and
the plurality of power semiconductor devices are each thermally coupled to the control board support base via the heat transfer member.

5. The vehicle mounted electrical power converter according to claim 1, wherein the circuit board is a metal board.

6. The vehicle mounted electrical power converter according to claim 1, wherein the vehicle mounted electrical power converter is an inverter that outputs an AC power to a motor that drives a vehicle.

7. The vehicle mounted electrical power converter according to claim 1, further comprising a control circuit that is mounted on or above the control board and that controls the power semiconductor device.
